(19) United States
(12) Patent Application Publication
(10) Pub. No.: US 2013/0271238 A1
(43) Pub. Date: Oct. 17, 2013

(54) FILTER DEVICE, MANUFACTURING METHOD FOR FILTER DEVICE, AND DUPLEXER

(71) Applicant: TAIYO YUDEN CO., LTD., Tokyo (JP)

(72) Inventors: Yosuke ONDA, Tokyo (JP); Taisei IRIEDA, Tokyo (JP); Tomoyuki TAKAHASHI, Tokyo (JP); Yuichi SASAJIMA, Tokyo (JP)

(73) Assignee: TAIYO YUDEN CO., LTD., Tokyo (JP)

(21) Appl. No.: 13/790,989

(22) Filed: Mar. 8, 2013

(30) Foreign Application Priority Data
Apr. 13, 2012 (JP) 2012-092032

(51) Int. Cl. H03H 9/70; H03H 9/64; H03H 9/54

(52) U.S. Cl. CPC H03H 9/54; H03H 9/706
USPC 333/133; 427/100; 156/280; 333/187; 333/195

(57) ABSTRACT

A transmitting/receiving filter (filter device) according to one embodiment of the present invention is provided with a transmitting filter, a receiving filter, and a support substrate. The transmitting filter includes a first resonator constituted of a BAW device (FBAR, SMR). The receiving filter includes a second resonator constituted of a Lamb wave device. The support substrate supports both the transmitting filter and the receiving filter. The transmitting filter and the receiving filter are constituted of elastic wave resonators that resonate at different oscillation modes from each other, which allows miniaturization of the support substrate to be realized while preventing oscillation interference between the two filters.

This application claims the benefit of Japanese Application No. 2012-092032, filed in Japan on Apr. 13, 2012, which is hereby incorporated by reference in its entirety.

### BACKGROUND OF THE INVENTION

1. Field of the Invention

The present invention relates to a filter device installed in a mobile communication device such as a mobile telephone, a manufacturing method for a filter device, and a duplexer.

2. Description of Related Art

In recent years, in order to speed up the transmission of data, the miniaturization of a duplexer and the ability to transmit and receive signals at a higher frequency and at a broader band are desired for a mobile communication device. A duplexer as mentioned in this specification is an element that splits the transmitted and received signals in order to use a single antenna for both types of signals in a communication system that uses frequency division, and is constituted of a plurality of filters that have different operating frequencies between the transmitting side and the receiving side. A transmitting filter and a receiving filter typically have a surface acoustic wave (SAW) filter, which has a high electromechanical coupling coefficient and a low transmission loss.

A conventional duplexer had a transmitting filter and a receiving filter formed on separate substrates, and thus, it was difficult to miniaturize the duplexer or simplify the manufacturing process. In order to solve this, in recent years, a method was disclosed in which the transmitting filter and the receiving filter are formed on the same substrate (refer to Patent Document 1 below, for example).

However, since the transmitting-side SAW filter and the receiving-side SAW filter, which are installed on the same substrate, respectively rely on resonation at the same oscillation mode, there is a problem that the oscillations between the two filters interfere with each other, thus reducing isolation characteristics. In order to solve this problem, a method is proposed in which a groove is formed between the transmitting and receiving filters, the gap between the transmitting and receiving filters is widened, or an improvement is made to the circuit configuration, for example (refer to Patent Document 2 below, for example).

### RELATED ART DOCUMENTS

### Patent Documents

Patent Document 1: Japanese Patent Application Laid-Open Publication No. 2001-308681

Patent Document 2: Japanese Patent Application Laid-Open Publication No. 2002-330057

### SUMMARY OF THE INVENTION

However, because forming a groove between the transmitting and receiving filters or widening the gap between the transmitting and receiving filters results in an increase in the size of the substrate, it is difficult to miniaturize the element.

Taking into consideration the above situation, an object of the present invention is to provide a filter device, a manufacturing method for a filter device, and a duplexer in which miniaturization can be achieved while maintaining excellent isolation characteristics.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present invention provides a filter device that includes: a first filter that includes a first elastic wave resonator configured to resonate in a first oscillation mode;

a second filter that includes a second elastic wave resonator configured to resonate in a second oscillation mode that differs from the first oscillation mode; and

a support substrate that supports both the first filter and the second filter.

In another aspect, the present invention provides a filter device that includes: a support substrate having a first region, and a second region formed on a same plane as the first region;

a first filter that is formed in the first region, the first filter including a first elastic wave resonator configured to resonate in a first oscillation mode; and

a second filter that is formed in the second region, the second filter including a second elastic wave resonator configured to resonate in a second oscillation mode that differs from the first oscillation mode.

In another aspect, the present invention provides a manufacturing method of a filter device, the method including:

forming a first electrode layer that is patterned into a prescribed shape on a first surface of a support substrate;

forming a piezoelectric layer on the first electrode layer and the first surface;

forming a second electrode layer on a first piezoelectric layer part of the piezoelectric layer opposite to the first electrode layer, the first piezoelectric layer part being formed on the first electrode layer;

forming an interdigital transducer layer as a third electrode layer on a second piezoelectric layer part of the piezoelectric layer, the second piezoelectric layer part being formed on the first surface; and

forming a first cavity opposite to the first electrode layer and a second cavity opposite to the second piezoelectric layer on a second surface of the support substrate opposite to the first surface of the support substrate.

In another aspect, the present invention provides a manufacturing method of a filter device, the method including:

forming a first electrode layer that is patterned into a prescribed shape on a first surface of a piezoelectric substrate;

bonding a support substrate to the first surface such that the first electrode layer is interposed therebetween;

forming a second electrode layer opposite to the first electrode layer through the piezoelectric substrate, and an interdigital transducer layer as a third electrode layer opposite to the support substrate through the piezoelectric substrate on a second surface of the piezoelectric substrate opposite to the first surface of the piezoelectric substrate; and

forming, in the support substrate, a first cavity opposite to the first electrode layer and a second cavity opposite to the third electrode layer through the piezoelectric substrate.

In another aspect, the present invention provides a duplexer that includes:

a first filter for transmitting that includes a first elastic wave resonator configured to resonate in a first oscillation mode;

a second filter for receiving that includes a second elastic wave resonator configured to resonate in a second oscillation mode that differs from the first oscillation mode; and

a support substrate that supports both the first filter and the second filter.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a block diagram that shows a configuration of a duplexer according to one embodiment of the present invention.

FIG. 2 is a circuit diagram that shows one example of a ladder-type filter.

FIG. 3 is a schematic view that shows frequency characteristics of a duplexer.

FIG. 4 is a schematic cross-sectional view that shows a configuration of a transmitting/receiving filter (filter device) according to one embodiment of the present invention.

FIG. 5 is a schematic plan view that shows a configuration of the transmitting/receiving filter.

FIGS. 6A through 6G are schematic cross-sectional views of main steps for describing a manufacturing method for the transmitting/receiving filter.

FIG. 7 is a schematic cross-sectional view that shows a configuration of a transmitting/receiving filter (filter device) according to Embodiment 2 of the present invention.

FIGS. 8A through 8E are schematic cross-sectional views of main steps for describing a manufacturing method for the transmitting/receiving filter shown in FIG. 7.

FIG. 9 is a schematic cross-sectional view that shows a configuration of a transmitting/receiving filter (filter device) according to Embodiment 3 of the present invention.

FIG. 10 is a schematic cross-sectional view that shows a configuration of a transmitting/receiving filter (filter device) according to Embodiment 4 of the present invention.

FIG. 11 is a graph that shows impedance characteristics of a series-arm resonator and a parallel-arm resonator, and describes a design method for a ladder-type filter. In FIG. 11, Bp represents the imaginary part of the admittance (Yp=Gp+jBp) of the parallel-arm resonator, and Xs represents the imaginary part of the impedance (Zs=Rs+jXs) of the series-arm resonator.

FIG. 12 is a schematic drawing that shows causes for a decrease in isolation characteristics of a one-chip SAW duplexer.

FIGS. 13A and 13B are schematic plan views that show a comparison of the size of the transmitting/receiving filter according to the present embodiment and a SAW filter according to a comparison example. FIG. 13A shows the SAW filter according to the comparison example and FIG. 13B shows the transmitting/receiving filter according to the present embodiment.

FIGS. 14A through 14C are schematic drawings that show the difference between a Lamb wave resonator and an FBAR. FIG. 14A shows oscillation modes, FIG. 14B shows electrode configurations, and FIG. 14C shows potential distributions.

FIG. 15 is a schematic cross-sectional view that shows a configuration of a transmitting/receiving filter (filter device) according to Embodiment 5 of the present invention.

### DETAILED DESCRIPTION OF THE PREFERRED EMBODIMENTS

A filter device according to one embodiment of the present invention is provided with a first filter, a second filter, and a support substrate.

The first filter includes a first elastic wave resonator configured to resonate in a first oscillation mode.

The second filter includes a second elastic wave resonator configured to resonate in a second oscillation mode that differs from the first oscillation mode.

The support substrate supports both the first filter and the second filter.

In the filter device, the first filter and the second filter are constituted of elastic wave resonators that resonate at different oscillation modes from each other, which prevents oscillation interference between the filters and allows excellent isolation characteristics to be attained. Also, the filter device can reduce the amount of space required to prevent such interference, which allows miniaturization of the support substrate.

The first filter and the second filter are typically formed on the same plane as each other on the support substrate, but each filter may be formed on a different plane of the support substrate.

As long as the first elastic wave resonator constituting the first filter and the second elastic wave resonator constituting the second filter resonate at different oscillation modes from each other, the elastic wave resonator is not limited. For example, one of the filters can be constituted of a bulk acoustic wave (BAW) resonator and the other filter can be constituted of a Lamb wave resonator or a surface acoustic wave resonator. Alternatively, one filter may be constituted of a Lamb wave resonator and the other filter may be constituted of a surface acoustic wave filter.

By having the first elastic wave resonator be constituted of a bulk wave resonator and having the second elastic wave resonator be constituted of a Lamb wave resonator, it is possible to operate the filters at sufficiently high frequencies while maintaining isolation characteristics.

Besides a film bulk acoustic resonator (FBAR), a solid mounted resonator (SMR) or the like can be used for the bulk wave resonator.

A filter device according to another embodiment of the present invention is provided with a support substrate, a first filter, and a second filter.

The support substrate has a first region, and a second region formed on the same plane as the first region.

The first filter is formed in the first region and includes a first elastic wave resonator configured to resonate in a first oscillation mode.

The second filter is formed in the second region and includes a second elastic wave resonator configured to resonate in a second oscillation mode that differs from the first oscillation mode.

Because the first filter and the second filter in the filter device are constituted of elastic wave resonators that resonate at different oscillation modes from each other, it is possible to effectively prevent oscillation interference between the filters even if they are formed on the same plane of the support substrate, and the support substrate can be miniaturized.

The first region and the second region are typically formed to be on the same plane as each other on the support substrate and adjacent to each other, but one region may be formed inside the other region.

The first elastic wave resonator is constituted of a bulk wave resonator, for example. In this case, the first elastic wave resonator has a first electrode layer formed in the first region, a first piezoelectric layer formed on the first electrode layer, and a second electrode layer formed on the first piezoelectric layer.

The second elastic wave resonator is constituted of a Lamb wave resonator or a surface acoustic wave resonator, for example. In this case, the second elastic wave resonator has a second piezoelectric layer formed in the second region, and an interdigital transducer layer formed on the second piezoelectric layer.

In the above-mentioned configuration examples, the first elastic wave resonator additionally has a first cavity formed in the first region opposite to the first electrode layer. In this case, a film bulk acoustic resonator (FBAR) is formed as the first elastic wave resonator. Also, an acoustic multilayer film may be formed in the first region opposite to the first electrode layer. In this case, a solid mounted resonator (SMR) is formed as the first elastic wave resonator.

The second elastic wave resonator may additionally have a second cavity formed in the second region opposite to the second piezoelectric layer. In this case, a Lamb wave resonator is configured as the second elastic wave resonator.

The first piezoelectric layer and the second piezoelectric layer may be formed at the same thickness. With this configuration, it is possible to form the first piezoelectric layer and the second piezoelectric layer of the same piezoelectric layer, thus simplifying the manufacturing process.

A manufacturing method of a filter device according to one embodiment of the present invention includes forming a first electrode layer patterned in a prescribed shape on a first surface of a support substrate.

A piezoelectric layer is formed on the first electrode layer and the first surface.

A second electrode layer opposite to the first electrode layer is formed on a first piezoelectric layer part of the piezoelectric layer, the first piezoelectric layer part being formed on the first electrode layer.

An interdigital transducer layer as a third electrode layer is formed on a second piezoelectric layer part of the piezoelectric layer, the second piezoelectric layer part being formed on the first surface.

A first cavity opposite to the first electrode layer and a second cavity opposite to the second piezoelectric part are formed on a second surface opposite to the first surface of the support substrate.

According to the manufacturing method of the filter device, it is possible to form on the same support substrate a bulk wave resonator that includes the first piezoelectric layer and a Lamb wave resonator or a surface acoustic wave resonator that includes the second piezoelectric layer. Because these resonators resonate at different oscillation modes from each other, there is no oscillation interference between the two, and both resonators can be formed without any limits to how close they are to each other, and thus, it is possible to miniaturize the substrate.

A manufacturing method of a filter device according to another embodiment of the present invention includes forming a first electrode layer patterned in a prescribed shape on a first surface of a piezoelectric substrate.

The support substrate is bonded to the first surface such that the first electrode layer is interposed therebetween.

A second electrode layer opposite to the first electrode layer through the piezoelectric substrate, and an interdigital transducer layer as a third electrode layer opposite to the support substrate through the piezoelectric substrate are formed on a second surface opposite to the first surface of the piezoelectric substrate.

A first cavity opposite to the first electrode layer and a second cavity opposite to the third electrode layer through the piezoelectric substrate are formed on the support substrate.

According to the manufacturing method of the filter device mentioned above, it is possible to form on the same support substrate a bulk wave resonator that includes the first piezoelectric layer and a Lamb wave resonator or a surface acoustic wave resonator that includes the second piezoelectric layer. With this configuration, it is possible to prevent oscillation interference between the two resonators and the substrate can be miniaturized.

In addition, a duplexer according to one embodiment of the present invention is provided with a first filter for transmitting, a second filter for receiving, and a support substrate.

The first filter includes a first elastic wave resonator configured to resonate in a first oscillation mode.

The second filter includes a second elastic wave resonator configured to resonate in a second oscillation mode that differs from the first oscillation mode.

The support substrate supports both the first filter and the second filter.

In the above-mentioned duplexer, it is possible to constitute the transmitting-side filter and the receiving-side filter of elastic wave resonators that resonate at different oscillation modes. As a result, because the transmitting and receiving filters use different oscillation modes, it is possible to provide a subminiature one-chip duplexer without needing to take into consideration oscillation interference between the two filters.

The above-mentioned duplexer may be additionally provided with a circuit board on which the support substrate is mounted. The circuit board has an antenna terminal that connects to both the first filter and the second filter, and a phase shifter provided between the antenna terminal and the second filter.

Embodiments of the present invention will be described below with reference to the drawings.

### Embodiment 1

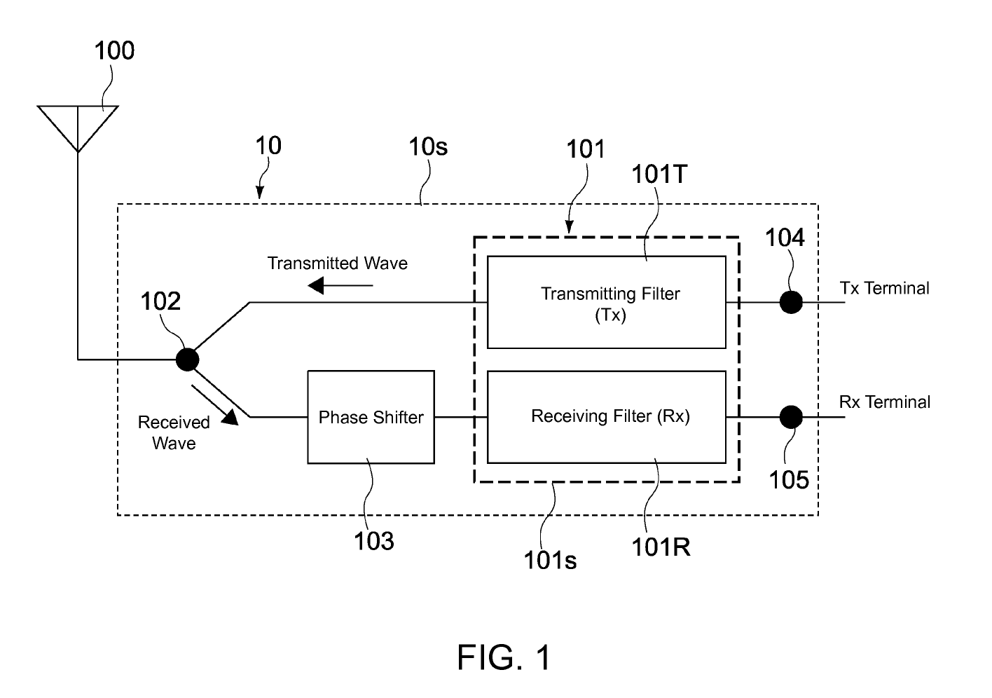

FIG. 1 is a block diagram that shows a configuration of a duplexer according to one embodiment of the present invention. First, a configuration of the duplexer will be described.

### <Duplexer>

A duplexer 10 of the present embodiment is a device that splits transmitted and received signals and is installed on a mobile communication device such as a mobile telephone. The duplexer 10 is used in a communication system such as FDD (frequency division duplex), which includes UMTS (universal mobile telecommunications system) and CDMA (code division multiple access), for example.

The duplexer 10 has the role of splitting the transmitted and received signals in order to use a single antenna for both transmitting and receiving signals. In order to realize this, the following properties are necessary.

(1) There is little leakage of the transmitted signal to the receiving signal band, and little leakage of the received signal to the transmitting signal band.

(2) An impedance Zt of the transmitting filter and an impedance Zr of the receiving filter fulfill the following conditions.

(Impedance Conditions)

Transmitting (Tx) Band: Zt=Z0<<Zr (Z0=50Ω)

Receiving (Rx) Band: Zr=Z0<<Zt

The duplexer 10 of the present embodiment basically has a transmitting/receiving filter 101 (filter device), an antenna terminal 102, a phase shifter 103, a transmitting port 104, and a receiving port 105.

The transmitting/receiving filter 101 includes a transmitting filter 101T and a receiving filter 101R, and both of these filters are made of elastic wave filters. The antenna terminal 102 connects the antenna 100 of the device to the transmitting/receiving filter 101, and the transmitting filter 101T and the receiving filter 101R are both connected to the antenna terminal 102.

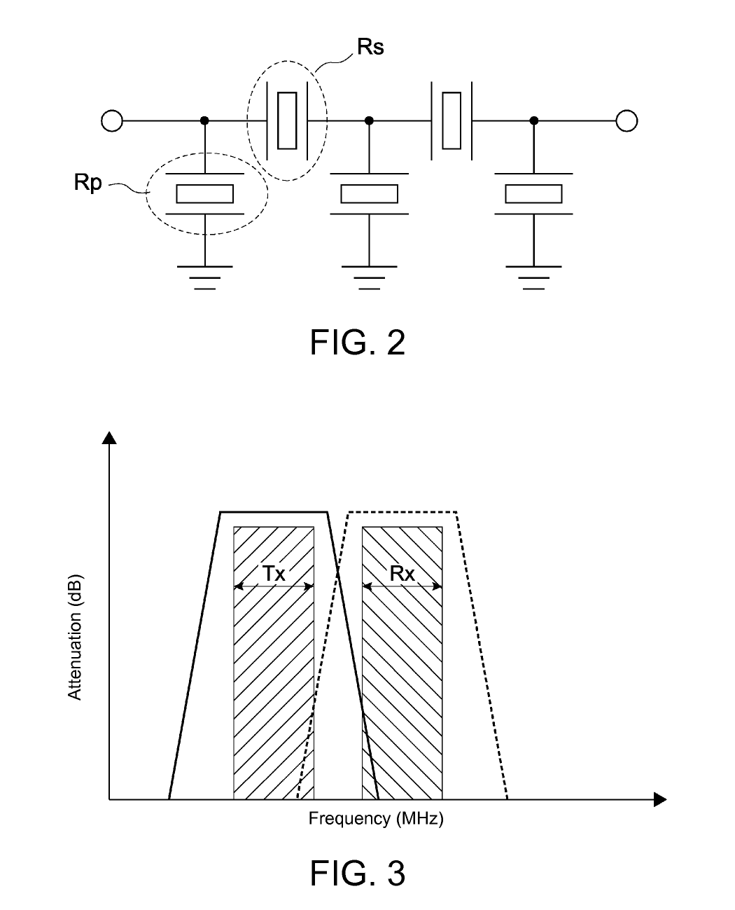

The transmitting filter 101T and the receiving filter 101R constitute a prescribed filter circuit. FIG. 2 shows one example of a configuration of a circuit of a ladder-type filter. The ladder-type filter is constituted of a plurality of resonators electrically connected in series and in parallel, and by having the resonance frequency of resonators connected in series (series-arm resonators) Rs be approximately the same as the resonance frequency of resonators connected in parallel (parallel-arm resonators) Rp, prescribed band-pass characteristics can be attained. By optimizing the number of connected resonators, or the ratio of capacitance between the series-arm resonators and the parallel-arm resonators, loss and attenuation in the filter can be mitigated.

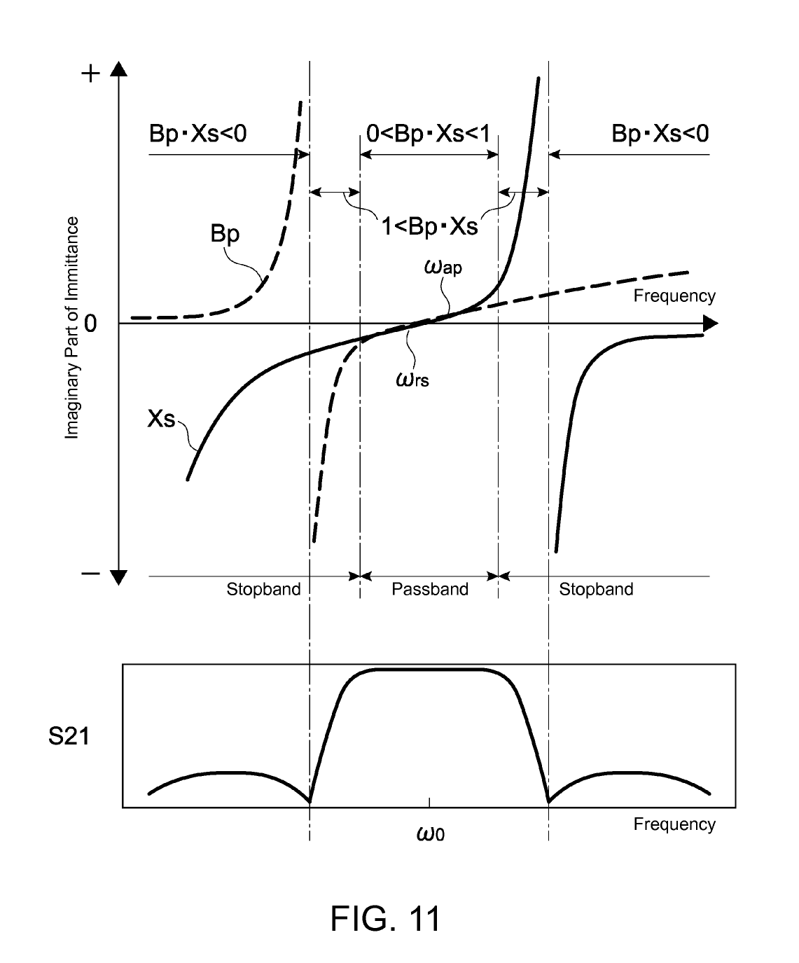

A method to design a typical ladder-type filter will be described with reference to FIG. 11. FIG. 11 is a graph that shows impedance characteristics of the series-arm resonators Rs and the parallel-arm resonators Rp.

First, the zero of the impedance of the series-arm resonator Rs is set equal to the pole of the impedance of the parallel-arm resonator Rp (ωap and ωrs). A pole frequency of an attenuation pole that satisfies the conditions is determined (refer to FIG. 11). Next, the configuration of the resonators that satisfies passband characteristics is determined. For example, in the case of a SAW filter, this means the overlap length, the number of pairs, and the like of the electrode. The resonators are configured such that the impedance Zin of the filter reaches infinity in the attenuation region and 50Ω in the passband region.

The phase shifter (or branching filter) 103 is provided between the antenna terminal 102 and the receiving filter 101R, and has the function of preventing the transmitted signal from entering the receiving filter 101R. A phase shifter may be provided between the antenna terminal 102 and the transmitting filter 101T for a similar purpose. The phase shifter 103 may be omitted as necessary.

The transmitting port 104 connects the transmitting filter 101T to the transmitting terminal (Tx terminal) of the device. The receiving port 105 connects the receiving filter 101R to the receiving terminal (Rx terminal) of the device.

The duplexer 10 is configured to be able to transmit and receive signals simultaneously via the antenna 100. The frequency characteristics of the duplexer 10 are shown schematically in FIG. 3. The duplexer 10 is constituted of filters with two different passbands, and the lower frequency side is the transmitting band while the higher frequency side is the receiving band.

A branching circuit or a branching line is used for the branching filter. If using a branching line, the line is designed to be at a sufficient length for the input impedance of the branching line and the receiving filter to be high throughout the entire attenuation band. The design method is described below.

The conditions for the receiving filter not to affect the transmitting filter in the duplexer are as follows.

The Rx route (branching line and receiving filter) input impedance Zin (L) from the perspective of the antenna terminal is given in formula (1).

Zin(L)=(cos θ+jsin θ/(Zin(Rx))/((cos θ/(−Zin(Rx)+jsin θ))) (1)

Here, θ=βL, β=2π/λ, L is the line length, and Zin(Rx) is the input impedance of the receiving filter.

If the phaseβ of the branching line is set to π/2, the branching line becomes a gyrator. When used as a gyrator, formula (1) becomes formula (2).

Zin(L)=1/(Zin(Rx)) (2)

In other words, if Zin(Rx)=0, then Zin(L)=∞, and interference in the Rx route is eliminated. In reality, Zin(Rx)=0 is not satisfied. Here, when Zin(Rx) is small and θ=(π/2)+Δθ, then formula (1) becomes formula (3).

Zin(L)=(−sin(Δθ)+jcos(Δθ)/(Zin(Rx))/((sin(Δθ)/(Zin(Rx)+jcos(Δθ)))) (3)

In formula (3), if the input impedance of the receiving filter Zin(Rx) is small, then the conditions that need to be fulfilled in order not to affect the transmitting filter are given in formula (4).

tan(Δθ)=−1/(Zin(Rx)) (4)

In other words, if Zin(Rx) is small, then if the line length of the branching line is corrected by Δθ, then the transmitting filter is not affected, as in Zin(Rx)=0.

In the present embodiment, the transmitting/receiving filter 101 is configured as a one chip part in which the transmitting filter 101T and the receiving filter 101R are installed on the same support substrate 101s. The duplexer 10 has a circuit board 10s on which the transmitting/receiving filter 101 is installed, and on the circuit board 10s, the antenna terminal 102, the phase shifter 103, the transmitting port 104, the receiving port 105, and a wiring line pattern that connects these are respectively formed.

The phase shifter 103 may be formed on the same substrate 101s as the transmitting/receiving filter 101. Also, at least one of the antenna terminal 102, the transmitting port 104, and the receiving port 105 may be formed on the same substrate 101s as the transmitting/receiving filter 101. Alternatively, all of the antenna terminal 102, the phase shifter 103, the transmitting port 104, and the receiving port 105 may be formed on the same substrate 101s as the transmitting/receiving filter 101, and in such a case, it is possible to configure the duplexer 10 from one chip.

### <Transmitting/Receiving Filter>

Next, the configuration of the transmitting/receiving filter 101 (filter device) of the present embodiment will be described.

In the present embodiment, the transmitting filter 101T includes a bulk acoustic wave resonator (also referred to as a “BAW resonator” below) as an elastic wave resonator, and the receiving filter 101R includes a Lamb wave resonator (also referred to as a “Lamb wave device” below) or a SAW resonator (also referred to as a “SAW device” below), which has a different oscillation mode from the BAW resonator, as an elastic wave resonator.

The BAW resonator has a multilayer structure in which a piezoelectric film made of AN, ZnO, PZT, or the like is sandwiched by metal films, which are electrode layers above and below the piezoelectric film, and is a resonator that relies on resonation in the vertical direction of the piezoelectric film itself as a result of applying an alternating current voltage between the electrode layers above and below. By combining a plurality of BAW resonators, band-pass filter characteristics can be realized. This combination can be realized by the same circuit configuration and design method as the ladder-type filter (FIG. 2) made of a filter that uses SAW resonators.

Depending on how bulk acoustic waves excited by the resonation in the piezoelectric film are confined in the piezoelectric film, the BAW resonator can be broadly classified into the following types: a film bulk acoustic resonator (also referred to as “FBAR” below); and a solid mounted resonator (also referred to as “SMR” below).

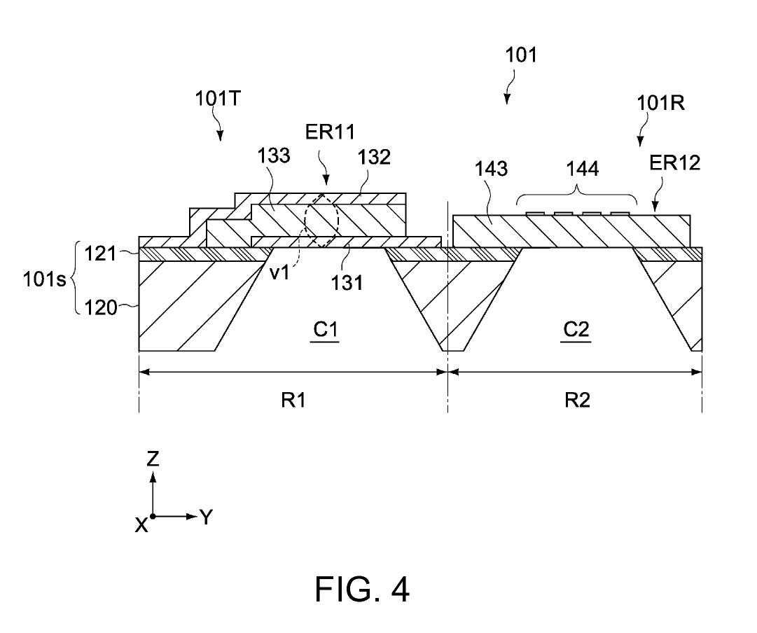

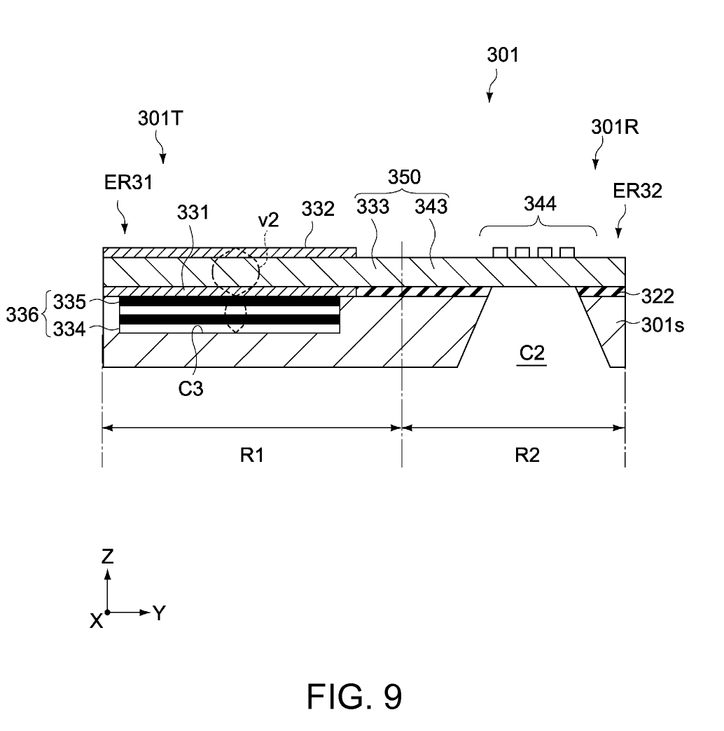

An FBAR has a cavity below the resonator and confines elastic waves by allowing the resonator to oscillate freely. A dashed line v1 shown on a first resonator ER11 in FIG. 4 is the elastic wave stress field (displacement), and FIG. 4 shows the elastic wave being confined by a first cavity C1. By contrast, the SMR has an acoustic multilayer film below the resonator, which reflects elastic waves. A dashed line v2 shown on a first resonator ER31 in FIG. 9 is the elastic wave stress field (displacement), and FIG. 9 shows the elastic wave being confined by an acoustic multilayer film 336.

The resonance frequency of the FBAR or the SMR is mostly determined by the thickness of the piezoelectric thin film and the speed of sound, and thus, the resonance frequency can be controlled by the thickness of the piezoelectric thin film. These resonators also have the advantage of having low loss levels and high power durability due to not having microelectrodes.

Surface acoustic waves (also referred to as “SAW” below) are a type of elastic wave that is propagated on the surface of a piezoelectric single crystal. By applying an alternating current voltage to periodically placed interdigital transducers (IDT) on the surface of the piezoelectric single crystal, a SAW of a frequency corresponding to the SAW propagation speed and the IDT electrode pitch is excited by the inverse piezoelectric effect. It is theoretically possible to have a SAW device with a higher resonance frequency by minimizing the electrode pitch, but due to problems related to electrode manufacturing techniques and power durability, the SAW device is not suitable to being used in high frequencies.

Lamb waves are a type of elastic wave like the surface acoustic waves (also referred to as “SAW” below), but unlike the SAW, which is propagated on the surface of the piezoelectric single crystal, the Lamb wave is propagated inside the piezoelectric single crystal, and is also referred to as a plate wave. A Lamb wave device has a cavity below the resonator, and needs a free surface for the oscillation of the piezoelectric single crystal. Like the SAW device, the Lamb wave is excited by applying an alternating current voltage to IDTs formed on the surface. The resonance frequency is determined by electrode pitch and the propagation speed of the Lamb wave, and the propagation speed depends on the thickness of the piezoelectric substrate. By minimizing the electrode pitch and making the piezoelectric substrate thin, it is possible to attain a higher frequency. The Lamb wave has the advantage of being propagated faster than the SAW, and thus, higher frequencies can be attained with greater ease.

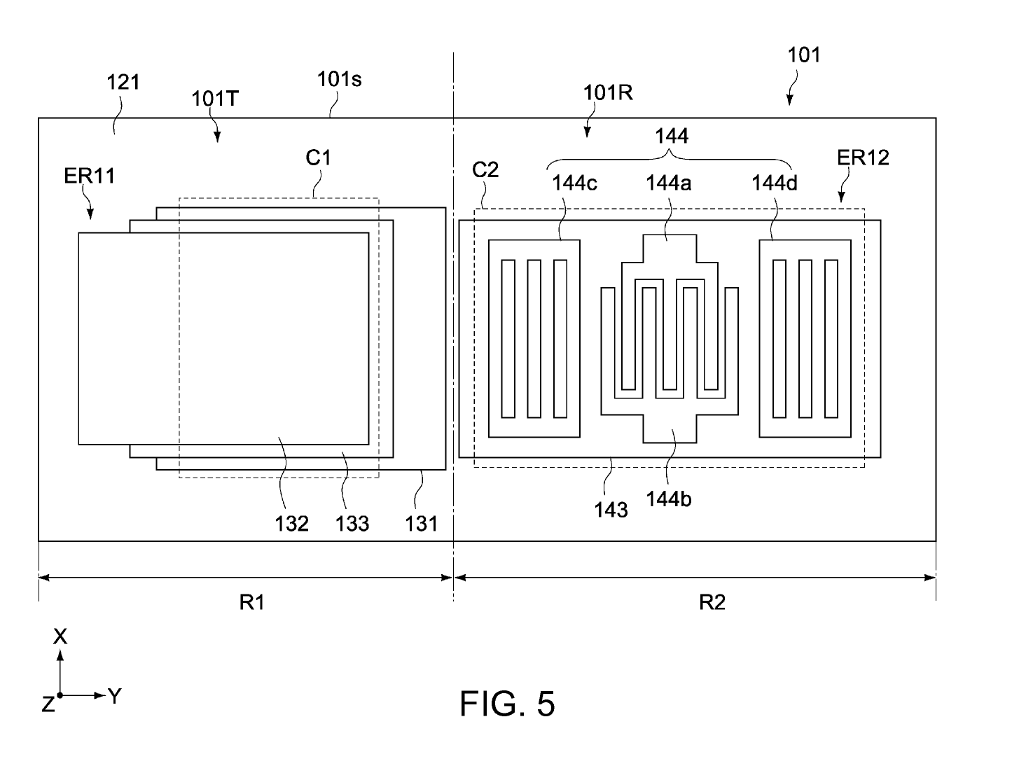

FIGS. 4 and 5 are a schematic cross-sectional view and a schematic plan view that show a configuration of the transmitting/receiving filter 101 of the present embodiment. The dimensions of the elements in the drawings differ from those of the actual elements and are exaggerated in the drawings. Also, the dimensional relationships are not necessarily the same between the drawings.

The transmitting/receiving filter 101 has the transmitting filter 101T (first filter) that includes the first resonator ER11 (first elastic wave resonator), the receiving filter 101R (second filter) that includes a second resonator ER12 (second elastic wave resonator), and the support substrate 101s that supports both the transmitting filter 101T and the receiving filter 101R. In the present embodiment, the first resonator ER11 is constituted of an FBAR, and the second resonator ER12 is constituted of a Lamb wave device.

### (Support Substrate)

The support substrate 101s has a main surface in parallel with an X axis and a Y axis that intersects perpendicularly therewith. The direction of the Z axis, which intersects perpendicularly with the X axis and the Y axis, indicates the thickness direction of the support substrate 101s. The support substrate 101s has a main substrate body 120 constituted of a silicon substrate, for example, and an insulating film 121 formed on an upper surface side (upper side of FIG. 4) of the main substrate body 120.

The silicon substrate used in the main substrate body 120 has advantages in being relatively inexpensive, having excellent surface flatness characteristics and temperature characteristics, and the like. Because the process of forming a thin film on the silicon substrate is well established, stable productivity can be attained. In addition, the FBAR (first resonator ER11) and the Lamb wave device (second resonator ER12) both have a piezoelectric thin film, and use the oscillation in the thickness direction of the piezoelectric thin film or the plate wave thereof. The piezoelectric thin film has a problem of lacking strength, and in the case of a sputtered film, a problem with stress, and therefore it cannot be kept as an independent part.

The insulating film 121 is constituted of a silicon oxide film, for example, but may be constituted of a silicon nitride film or the like. The thickness of the insulating film 121 is not limited, and is formed at a thickness that can guarantee electrical insulation between the main substrate body 120, and the transmitting filter 101T and the receiving filter 101R (approximately 100 nm, for example).

The support substrate 101s has a first region R1 where the first resonator ER11 is formed, and a second region R2 where the second resonator ER12 is formed. In the present embodiment, the first region R1 and the second region R2 are designed to be adjacent to each other on the upper surface side of the support substrate 101s.

### (Transmitting Filter)

The first resonator ER11 has a lower electrode layer 131 (first electrode layer), an upper electrode layer 132 (second electrode layer), and a piezoelectric layer 133 (first piezoelectric layer). The lower electrode layer 131, the upper electrode layer 132, and the piezoelectric layer 133 are respectively formed on the insulating film 121 in the first region R1 of the support substrate 101s, and the piezoelectric layer 133 is disposed between the lower electrode layer 131 and the upper electrode layer 132.

Materials for the lower electrode layer 131 and the upper electrode layer 132 are not limited; the lower electrode layer 131 and the upper electrode layer 132 are made of a metal material with a high acoustic impedance such as Ru (ruthenium) and Mo (molybdenum), for example. The thickness of the lower electrode layer 131 and the upper electrode layer 132 is not limited either, and is approximately 200 nm, for example.

The piezoelectric layer 133 is constituted of AN (aluminum nitride), for example, but is of course not limited to this. The thickness of the piezoelectric layer 133 is not limited either; the thickness is appropriately set according to the desired transmitting frequency band, and is approximately 500 nm in the present embodiment.

The first resonator ER11 additionally has a first cavity C1. The first cavity C1 is formed in the first region R1 of the support substrate 101s opposite to the lower electrode layer 131. With this configuration, a freely oscillating end is formed on both surfaces of the piezoelectric layer 133, and by confining elastic waves between the lower electrode layer 131 and the upper electrode layer 132, it is possible to allow the resonator to oscillate freely.

In the present embodiment, the first cavity C1 is constituted of a hole that penetrates the support substrate 101s, but is not limited to this; the first cavity C1 may be constituted of a recess with a bottom that is formed on the upper surface side of the support substrate 101s. The first cavity C1 may be formed to a depth that exposes the lower electrode layer 131 from the lower surface side of the support substrate 101s, or to leave at least a portion of the insulating film 121 remaining.

In the first resonator ER11 configured as stated above, an input-side terminal is connected to the lower electrode layer 131 and an output-side terminal is connected to the upper electrode layer 132, for example. The transmitting filter 101T may be constituted of one resonator ER11, but is typically constituted of a ladder-type circuit in which a plurality of resonators ER11 are connected to each other as shown in FIG. 2 on the first region R1, although this is not shown in drawings.

### (Receiving Filter)

The second resonator ER12 has a piezoelectric layer 143 (second piezoelectric layer) and an interdigital transducer layer 144. The piezoelectric layer 143 is formed on the insulating film 121 corresponding to the second region R2 of the support substrate 101s, and the interdigital transducer layer 144 is formed on the surface of the piezoelectric layer 143.

The piezoelectric layer 143 is made of AlN, for example, like the piezoelectric layer 133. The thickness of the piezoelectric layer 143 is the same as that of the piezoelectric layer 133 in the present embodiment (approximately 500 nm).

As shown in FIG. 5, the interdigital transducer layer 144 has a pair of interdigital transducers (IDTs) 144a and 144b, which face each other in the X-axis direction, and a pair of reflectors 144c and 144d, which sandwich this pair of interdigital transducers 144a and 144b opposite to each other in the Y direction. The material for the interdigital transducer layer 144 is not limited, and is a metal or the like such as aluminum (Al), an Al-Cu alloy that includes minute amounts of Cu (copper) for increasing power durability, Cu, Ti (titanium), and Cr (chromium), for example. The electrode pitch of the IDTs, which are included in the interdigital transducer layer 144, is appropriately set according to the desired receiving frequency band. The thickness of the interdigital transducer layer 144 may be the same as that of the upper electrode layer 132 of the first resonator ER11, but in the present embodiment, is thinner than the upper electrode layer 132.

The second resonator ER12 additionally has a second cavity C2. The second cavity C2 is formed in the second region R2 of the support substrate 101s opposite to the piezoelectric layer 143. As a result, ends that oscillate freely are formed on both surfaces of the piezoelectric layer 143.

If the second resonator ER12 is constituted of a SAW device, then it is unnecessary to form the second cavity C2.

In the present embodiment, the second cavity C2 is constituted of a hole that penetrates the support substrate 101s, but is not limited to this; the second cavity C2 may be constituted of a recess with a bottom that is formed on the upper surface side of the support substrate 101s. The second cavity C2 may be formed to a depth that exposes the piezoelectric layer 143 from the lower surface side of the support substrate 101s, or to leave at least a portion of the insulating film 121 remaining.

In the second resonator ER12 configured as stated above, an input terminal is connected to one interdigital transducer 144a and an output terminal is connected to the other interdigital transducer 144b, for example. The receiving filter 101R may be constituted of one resonator ER12, but is typically constituted of a ladder-type circuit or a double mode circuit in which a plurality of resonators ER12 are connected to each other as shown in FIG. 2 in the second region R2, although this is not shown in drawings.

### <Manufacturing Method for Transmitting/Receiving Filter>

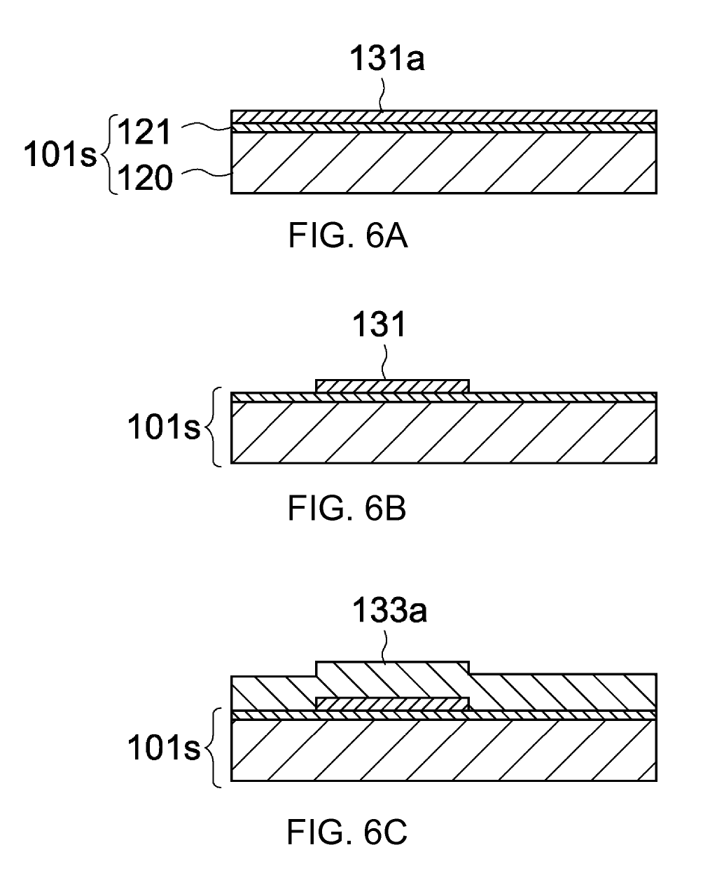

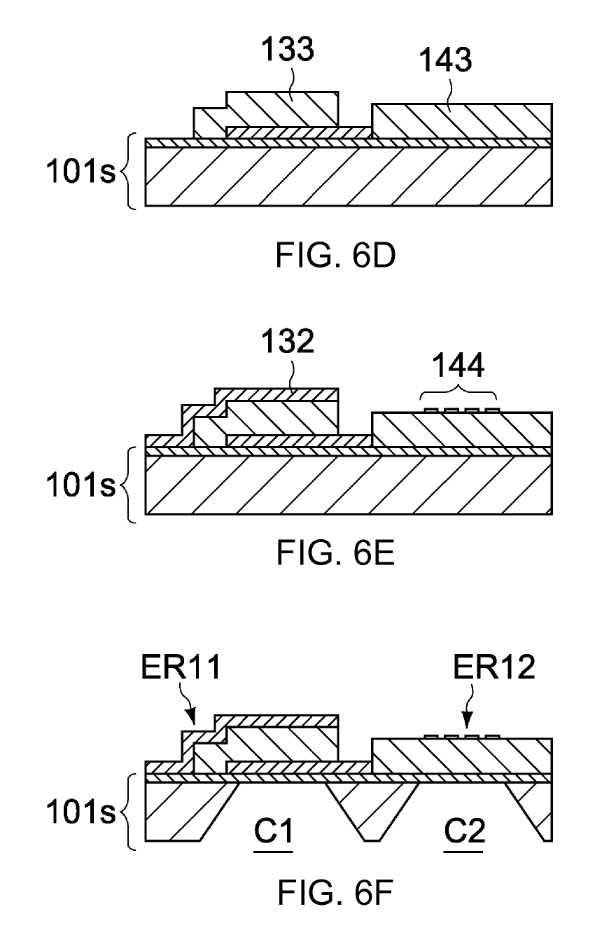

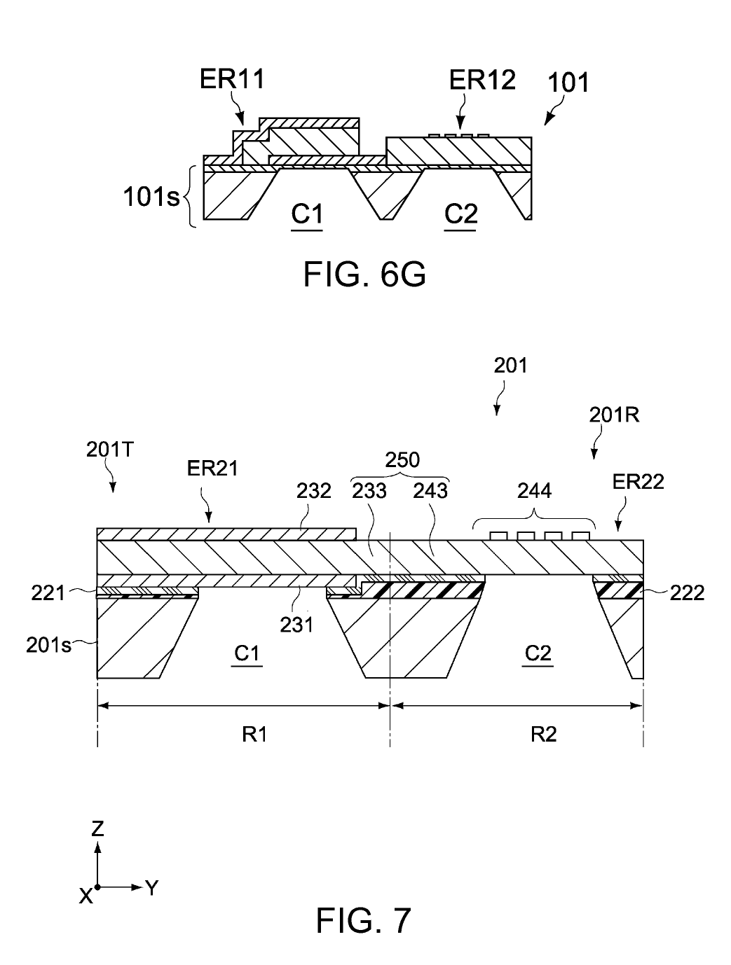

Next, a manufacturing method for the transmitting/receiving filter 101 configured as stated above will be described. FIGS. 6A to 6G are schematic cross-sectional views that show main steps of a manufacturing method of the transmitting/receiving filter 101. In the present embodiment, the support substrate 101s is made of a silicon wafer, and a plurality of transmitting/receiving filters 101 are formed simultaneously at wafer level.

First, a metal film 131a, which constitutes the lower electrode layer 131, is formed on a surface of the support substrate 101s (the surface of the insulating film 121) to a thickness of approximately 200 nm (FIG. 6A). The metal film 131a is made of a Ru film, a Mo film, or the like, and the film is formed by the sputtering method, the vacuum evaporation method, or the like. The metal film 131a is patterned into a prescribed shape by the known photolithography method or the lift-off method, and as a result, the lower electrode layer 131 is formed in the first region R1 of the support substrate 101s (FIG. 6B).

Next, a piezoelectric film 133a is formed on the surface on the support substrate 101s, which includes the lower electrode layer 131 (FIG. 6C). The piezoelectric film 133a is an AlN film, and is formed by the reactive sputtering method in a nitrogen atmosphere, for example.

The piezoelectric film 133a is used by the piezoelectric layer 133 (first piezoelectric layer) of the first resonator ER11 and the piezoelectric layer 143 (second piezoelectric layer) of the second resonator ER12. The thickness of the piezoelectric film 133a is set according to the center frequency of the first resonator ER11 (FBAR) (approximately 500 nm, for example). The center frequency of the second resonator ER12 (Lamb wave device) can be adjusted by adjusting the IDT pitch, and thus, the AlN film thickness can be made the same for both the FBAR and the Lamb wave device, and extra processes can be eliminated.

The piezoelectric film 133a is patterned into a prescribed shape by the known photolithography method or the lift-off method, and as a result, the first piezoelectric layer 133 and the second piezoelectric layer 143 are formed on the support substrate 101s (FIG. 6D). In the present embodiment, the first piezoelectric layer 133 and the second piezoelectric layer 143 are separated, but the present invention is not limited thereto.

Next, the upper electrode layer 132 is formed on the first piezoelectric layer 133, and the interdigital transducer layer 144 (third electrode layer) is formed on the second piezoelectric layer 143 (FIG. 6E).

In the present embodiment, the upper electrode layer 132 is made of Ru or Mo, and the interdigital transducer layer 144 is made of Al. Thus, when the upper electrode layer 132 is formed, the second piezoelectric layer 143 is protected by a photoresist or the like, and when the interdigital transducer layer 144 is formed, the first piezoelectric layer 133 is protected by a photoresist or the like. The order in which the upper electrode layer 132 and the interdigital transducer layer 144 are formed is not limited, and for example, the interdigital transducer layer 144 is formed after the upper electrode layer 132 is formed.

The upper electrode layer 132 and the interdigital transducer layer 144 are formed by the vacuum evaporation method, the sputtering method, or the like, and after being formed, are patterned into a prescribed shape by the known photolithography method or the lift-off method. The IDT pitch of the interdigital transducer layer 144 is set according to the desired center frequency of the second resonator (Lamb wave device) ER12. The upper electrode layer 132 is 200 nm in thickness, for example, and the interdigital transducer layer 144 is 100 nm in thickness, for example.

Next, the first and second cavities C1 and C2 are each formed in the support substrate 101s (FIGS. 6F and 6G). The first and second cavities C1 and C2 are formed simultaneously using the reactive ion etching (RIE) technique from the lower surface side of the support substrate 101s (main substrate body 120), for example. In this case, the insulating film (silicon oxide film) 121, which has a lower etch rate than the main substrate body (silicon substrate) 120, functions as an etch-stop layer, and thus an appropriate etching process is realized (FIG. 6F). The insulating film 121 is etched as necessary (FIG. 6G). Minor adjustments of the center frequency of the resonators ER11 and ER12 may be conducted by adjusting the thickness of the insulating film 121.

The transmitting/receiving filter 101 is manufactured as stated above. According to the present embodiment, it is possible to make the components in common between the FBAR (first resonator ER11) and the Lamb wave device (second resonator ER12) (for example, forming the piezoelectric layers 133 and 143, and forming the first and second cavities C1 and C2) in one step. By being able to make the parts in common between the two resonators in one step, the number of steps is reduced compared to if the FBAR and the Lamb wave device were made separately, thus reducing the manufacturing cost.

### <Effects of the Present Embodiment>

There are two main causes for the isolation characteristics to decrease for a one-chip SAW duplexer that uses the SAW devices for the transmitting filter and the receiving filter, respectively.

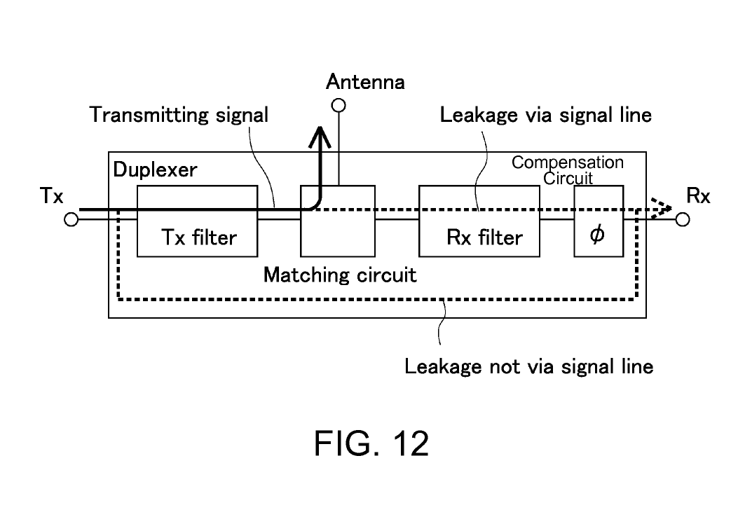

(Cause 1) As shown in FIG. 12, this type of one-chip SAW duplexer has a structure in which a matching circuit is inserted respectively between the transmitting filter (Tx filter), the receiving filter (Rx filter), and the antenna. Most of the transmitted signal flows to the antenna terminal from the Tx terminal, but because there is a limit on the impedance ratio of the Tx line (from the Tx terminal to the antenna terminal) and the Rx line (antenna terminal to the Rx terminal), a significant amount of signal leakage occurs from the Tx line to the Rx line (corresponding to the “Leakage via signal line” in FIG. 12). Another cause is that there is a significant amount of signal flow due to parasitic capacitance, signal line coupling, and the like (corresponding to “Leakage not via signal line” in FIG. 12).

(Cause 2) In a one-chip duplexer in which the Rx filter and the Tx filter are formed on the same substrate, oscillation leaks occur between these adjacent SAW filters, and as a result of this coupling, attenuation characteristics of the Tx filter and the Rx filter interfere with each other.

In order to eliminate the above-mentioned causes and realize high isolation characteristics, circuit-based techniques such as adding a phase compensation circuit (FIG. 12) that can cancel signal leakage from both directions were used, or a slit was provided between both filters as in Patent Document 2, thus minimizing interference from leaked signals. However, because a technique in which a groove is formed between the filters or a technique in which the gap between the filters is widened increases the size of the substrate, it was difficult to miniaturize the elements.

By contrast, in the transmitting/receiving filter 101 of the present embodiment, the transmitting filter 101T and the receiving filter 101R are constituted of the elastic wave resonators ER11 and ER12, which resonate at different oscillation modes from each other. By using different oscillation modes for the transmitting-side resonator and the receiving-side resonator, it is possible to prevent most interference between the two sides. As a result, it is possible to reduce to a minimum the amount of space provided for preventing interference, which allows a resonator, a transmitting/receiving filter, and a duplexer that are smaller than conventional devices and can handle higher frequencies and high electrical power to be provided.

A comparison between the size of the transmitting/receiving filter of the present embodiment and the chip size of a SAW duplexer with a slit formed between the transmitting filter and the receiving filter is described below.

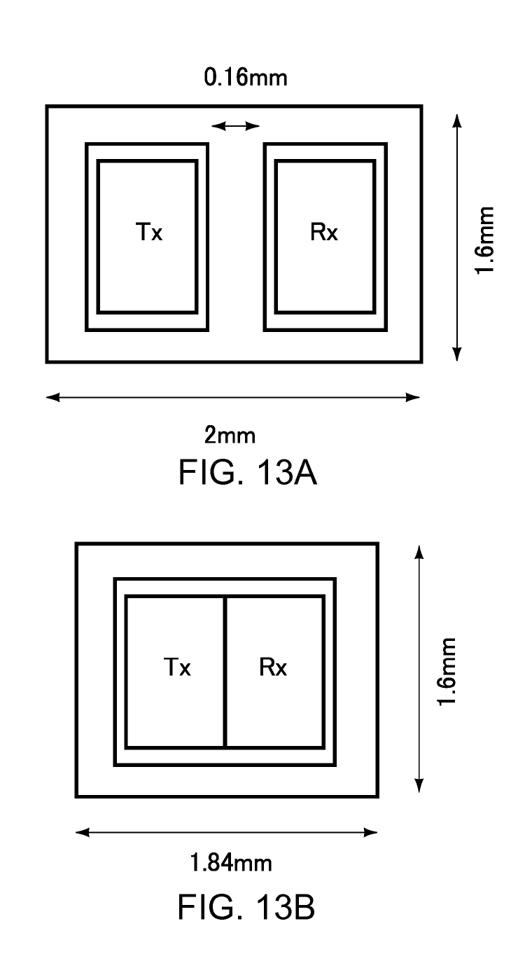

As shown in FIG. 13A, for example, a transmitting filter (Tx) and a receiving filter (Rx) with a horizontal length of 0.77 mm and a vertical length of 1.22 mm are respectively mounted on a SAW duplexer with a horizontal length of 2 mm and a vertical length of 1.6 mm. In order to prevent elastic wave interference, a gap of 80 μm is provided between the Tx and Rx. Also, the Tx and the Rx have margins of approximately 40 μm on the four sides of each chip, which are necessary for mounting. A one-chip duplexer in which the filter sizes of the FBAR and the Lamb wave device are the same as above, and which is made with the same layout as FIG. 13A, is shown in FIG. 13B. By forming the FBAR and the Lamb wave device on the same substrate, it becomes unnecessary to provide a gap of 80 μm between the Tx and Rx, or to form margins on the sides where the Rx and the Tx face each other (40 μm×2). As a result, it is possible to reduce the area by at least approximately 8%.

According to the present embodiment, by forming the transmitting/receiving filter 101 as one chip, not only is miniaturization achieved, but mounting becomes more flexible, and it is possible to form other devices and circuits on the same substrate monolithically.

If the duplexer 10 can be miniaturized, the wiring line length becomes shorter, which reduces loss in the wiring lines, thus reducing passband loss. Also, through miniaturization, it is possible to increase the number of chips per wafer, by which a reduction in manufacturing costs can be attained.

In the present embodiment, the resonator ER11 on the transmitting side is constituted of an FBAR, and the resonator ER12 on the receiving side is constituted of a Lamb wave device, which means that compared to a case in which a SAW device is used, the Q factor is higher, and the filter characteristics can be improved. Also, handling of higher frequency bands and application to various bands becomes possible. In particular, a Lamb wave device can achieve a high Q factor, which means that it is suited for use in the receiving side where steep attenuation characteristics are demanded.

### <Interference Between the Lamb Wave Resonator and the FBAR>

The Lamb wave resonator and the FBAR both use a piezoelectric thin plate, but have different oscillation modes. Differences between the modes will be described below.

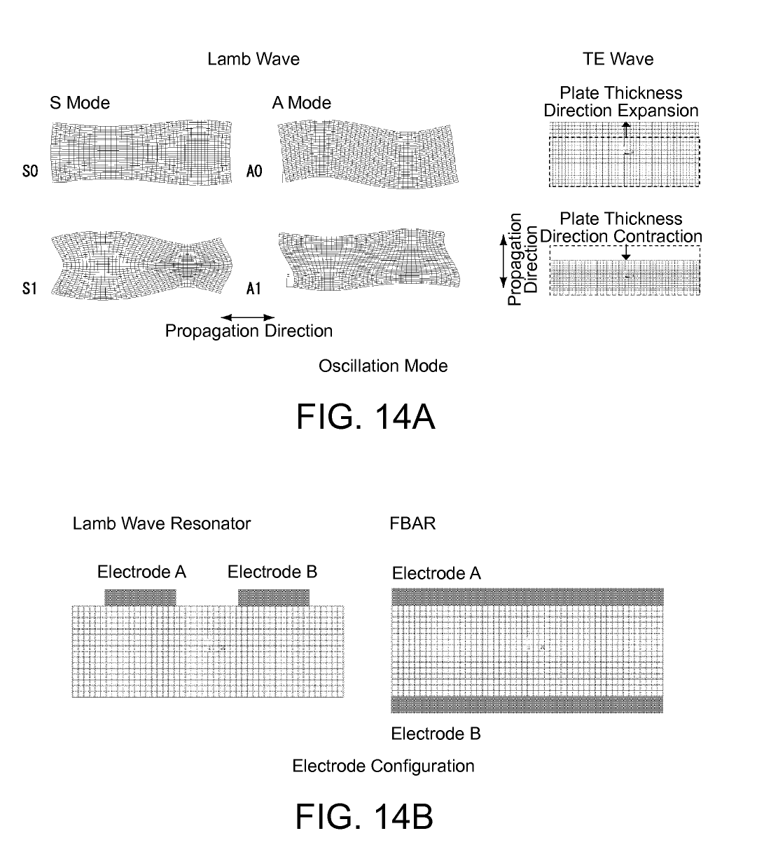

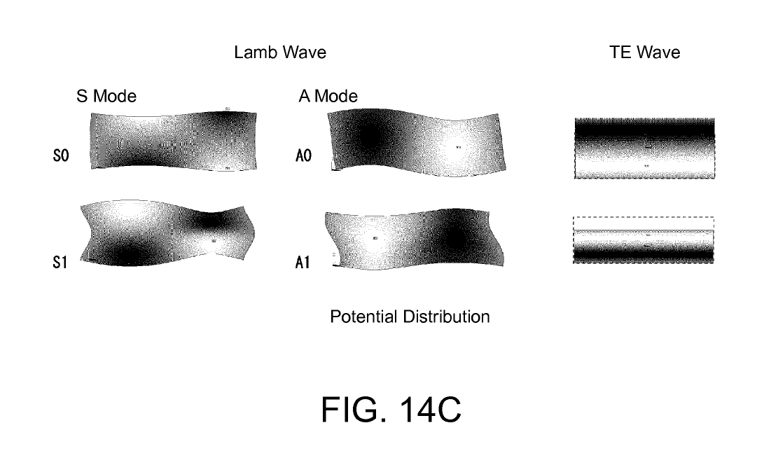

The Lamb wave is a plate wave that is propagated in the thin plate planar direction, and is a type of bulk wave. The Lamb wave has, as oscillation components, an SV (shear vertical) wave and an L (longitudinal) wave and these waves combine in a complex fashion on both surfaces of the thin plate while changing modes. Specific examples of mode shapes include an S (symmetric) mode shown on the left side of FIG. 14A in which the upper surface and the lower surface of the thin plate symmetrically contract, expand, and bend repeatedly, and an A (asymmetric) mode shown in the center of FIG. 14A in which the upper surface and the lower surface of the thin plate asymmetrically contract, expand, and bend repeatedly. In each drawing, a fundamental mode (S0, A0) and a high order oscillation mode (S1, A1) are respectively shown for one wavelength of the Lamb wave.

The FBAR is a resonator that uses longitudinal waves that are propagated in the plate thickness direction. The longitudinal wave oscillation of a Lamb wave (L wave) expands and contracts in the plate planar direction, but the longitudinal wave of the FBAR is a TE (thickness extension) wave that expands and contracts in the plate thickness direction as shown on the right side of FIG. 14A.

Both modes differ in propagation direction as stated above, and thus, the positions of the electrodes for each resonator also differ. In the case of a Lamb wave resonator, as shown on the left side of FIG. 14B, an interdigital transducer in which electrodes of different polarities are disposed at intervals of half a wavelength in the propagation direction is used. In the case of a TE wave, as shown on the right side of FIG. 14B, the propagation direction is the plate thickness direction, and thus, the electrodes are formed on the upper and lower sides of the thin plate. By doing so, the Lamb wave and the TE wave can each be efficiently excited or detected.

Both resonators have in common the fact that they use a thin plate oscillation mode, and thus can be formed on the same substrate. The interference between the oscillation modes in this case will be described below.

First, the TE wave is a wave propagated in the plate thickness direction, and thus, has little possibility of affecting the adjacent Lamb wave resonator side. However, the Lamb wave is propagated through the thin plate, and thus has the possibility of reaching the adjacent FBAR. Thus, possible interference mainly falls under the latter category.

However, even with the latter, the FBAR has electrodes on the entire upper surface and the entire lower surface, and these cancel out (attenuate) the voltage distribution resulting from the propagation of the Lamb wave, and thus, it is difficult for the Lamb wave to be propagated into the FBAR. Thus, the effect of the Lamb wave oscillation on the FBAR can effectively be disregarded.

FIG. 14C shows results of a simulation that shows potential distribution in the Lamb wave resonator and the FBAR shown in FIG. 14A. As shown in the drawing, with the Lamb wave, voltages with different polarities are generated alternatingly on the thin plate surface.

If a Lamb wave with such characteristics enters the FBAR, the upper surface and the lower surface of the FBAR have an electrical short, and thus, periodic potential distribution cannot occur. As a result, the Lamb wave attenuates sharply as soon as it enters the FBAR, and thus, the effects on the RF characteristics of the FBAR can also effectively be disregarded.

### Embodiment 2

FIG. 7 is a schematic cross-sectional view that shows a configuration of a transmitting/receiving filter according to Embodiment 2 of the present invention. Configurations that differ from those of Embodiment 1 will mainly be described below. Configurations similar to the above embodiment are assigned similar reference characters, and descriptions thereof are omitted or simplified.

A transmitting/receiving filter 201 of the present embodiment includes a transmitting filter 201T, a receiving filter 201R, and a support substrate 201s. The transmitting filter 201T has an FBAR as a first resonator ER21, and is formed in a first region R1 on the support substrate 201s. The receiving filter 201R has a Lamb wave device as a second resonator ER22, and is formed in a second region R2 on the support substrate 201s.

The first resonator ER21 has a lower electrode layer 231 (first electrode layer), an upper electrode layer 232 (second electrode layer), and a piezoelectric layer 233 (first piezoelectric layer). The lower electrode layer 231, the upper electrode layer 232, and the piezoelectric layer 233 are each formed in the first region R1 of the support substrate 201s, and the piezoelectric layer 233 is disposed between the lower electrode layer 231 and the upper electrode layer 232.

Materials for the lower electrode layer 231 and the upper electrode layer 232 are not limited; the lower electrode layer 231 and the upper electrode layer 232 are made of a metal material with a high acoustic impedance such as Ru (ruthenium) and Mo (molybdenum), for example. The thickness of the lower electrode layer 231 and the upper electrode layer 232 is not limited either, and is approximately 200 nm, for example.

The piezoelectric layer 233 is made of a piezoelectric single crystal substrate made of LT (lithium tantalate), LN (lithium niobate), or the like. The thickness of the piezoelectric layer 233 is not limited either, and is appropriately set according to the desired transmitting frequency band, and is approximately 1000 nm in the present embodiment.

The first resonator ER21 additionally has a first cavity C1. The first cavity C1 is formed in the first region R1 of the support substrate 201s opposite to the lower electrode layer 231. As a result, ends that oscillate freely are formed on both surfaces of the piezoelectric layer 233.

The second resonator ER22 has a piezoelectric layer 243 (second piezoelectric layer) and an interdigital transducer layer 244. The piezoelectric layer 243 is formed in the second region R2 of the support substrate 201s, and the interdigital transducer layer 244 is formed on the surface of the piezoelectric layer 243.

The piezoelectric layer 243 is made of an LT substrate or an LN substrate, for example, like the piezoelectric layer 233. In the present embodiment, the thickness of the piezoelectric layer 243 is the same as that of the piezoelectric layer 233 (approximately 1000 nm). In the present embodiment, the piezoelectric layer 233 and the piezoelectric layer 243 are constituted of the same piezoelectric single crystal substrate 250.

The interdigital transducer layer 244, like the interdigital transducer layer 144 of Embodiment 1, includes a pair of interdigital transducers (IDT) and a pair of reflectors that sandwich the pair of interdigital transducers. The material for the interdigital transducer layer 244 is not limited, and is a metal or the like such as aluminum (Al), an Al-Cu alloy that includes minute amounts of Cu (copper) for increasing power durability, Cu, Ti (titanium), and Cr (chromium), for example. The electrode pitch of the IDTs, which constitute the interdigital transducer layer 244, is appropriately set according to the desired receiving frequency band. The thickness of the interdigital transducer layer 244 may be the same as that of the upper electrode layer 232 of the first resonator ER21, but in the present embodiment, is thinner than the upper electrode layer 232.

The second resonator ER22 additionally has a second cavity C2. The second cavity C2 is formed in the second region R2 of the support substrate 201s opposite to the piezoelectric layer 243. As a result, ends that oscillate freely are formed on both surfaces of the piezoelectric layer 243.

The support substrate 201s is constituted of a silicon substrate, and supports both the transmitting filter 201T and the receiving filter 201R. The support substrate 201s, and the transmitting filter 201T and the receiving filter 201R are bonded to each other with a bonding layer 222 and an insulating film 221 interposed therebetween in this order from the side of the support substrate 201s.

The transmitting/receiving filter 201 of the present embodiment configured as stated above constitutes a duplexer by being installed on a circuit board 10s. According to the present embodiment, the transmitting filter 201T and the receiving filter 201R are constituted of the elastic wave resonators ER21 and ER22, which resonate at different oscillation modes from each other, and thus, as in Embodiment 1, it is possible to provide a transmitting/receiving filter on one chip and a miniature duplexer that can prevent oscillation interference between the filters.

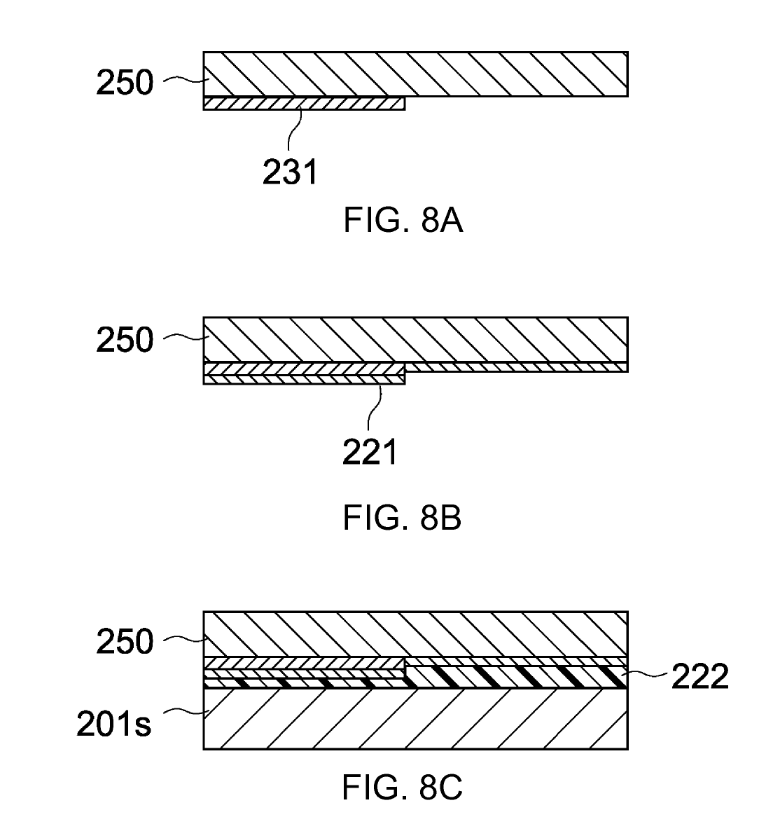

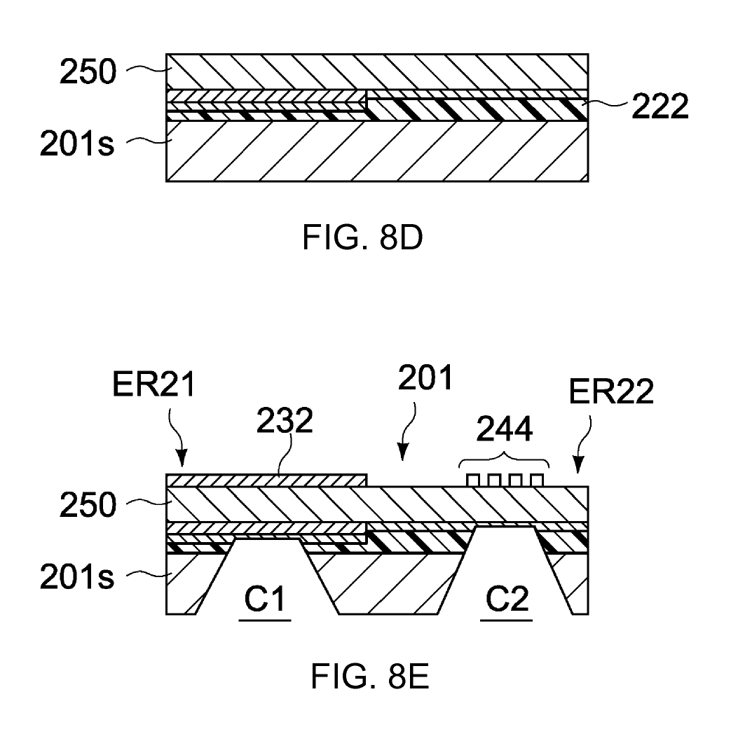

FIGS. 8A to 8E are schematic cross-sectional views that show main steps of a manufacturing method of the transmitting/receiving filter 201 of the present embodiment.

First, a lower electrode layer 231, which is patterned into a prescribed shape, is formed on the lower surface of the piezoelectric substrate 250 of a prescribed thickness (FIG. 8A). The lower electrode layer 231 is formed by the sputtering method, the vacuum evaporation method, or the like, and then patterned into a prescribed shape by the known photolithography method or the lift-off method.

Next, the insulating film 221 is formed on the lower surface of the piezoelectric substrate 250, which includes the lower electrode layer 231 (FIG. 8B). The insulating film 221 is a silicon oxide film, for example, and is formed by the vacuum evaporation method, the sputtering method, the CVD method, or the like. The thickness is not limited, and is approximately 100 nm, for example.

Next, with the insulating film 221 opposite to the support substrate 201s, the piezoelectric substrate 250 is bonded onto the support substrate 201s via the bonding layer 222. The bonding layer 222 is made of a synthetic resin material such as a thermoplastic resin or a thermosetting resin, for example. Alternatively, an adhesive tape or the like may be used as the bonding layer 222.

Next, the piezoelectric substrate 250 is thinned to a prescribed thickness (approximately 1000 nm, for example) as necessary (FIG. 8D). The thickness of the piezoelectric substrate 250 is set according to the center frequency of the first resonator ER21 (FBAR). Similar to Embodiment 1, the center frequency of the second resonator ER22 (Lamb wave device) can be set by the IDT pitch, and thus, by making the thickness of the first piezoelectric layer 233 and the second piezoelectric layer 243 the same, extra processes can be omitted.

As for a thinning process, the chemical mechanical polishing (CMP) technique is used, for example. By thinning the piezoelectric substrate 250 after bonding it to the support substrate 201s, the handling ability thereof can be improved.

Then, the upper electrode layer 232, which is opposite to the lower electrode layer 231 through the piezoelectric substrate 250, is formed on the upper surface of the piezoelectric substrate 250 in a prescribed location, and in addition, the interdigital transducer layer 244, which is opposite to the support substrate 201s through the piezoelectric substrate 250, is formed. Then, the first and second cavities C1 and C2 are respectively formed in the support substrate 201s, and the transmitting/receiving filter 201 of the present embodiment is completed (FIG. 8E).

The first and second cavities C1 and C2 are formed by methods similar to the above-mentioned Embodiment 1. In this step, minor adjustments may be made to the center frequency of the resonators ER21 and ER22 by adjusting the thickness of the insulating film 221 and the bonding layer 222.

According to the present embodiment, it is possible to make the components in common between the FBAR (first resonator ER21) and the Lamb wave device (second resonator ER22) (for example, forming the piezoelectric layers 233 and 243, and forming the first and second cavities C1 and C2) in one step. By being able to make the parts in common between the two resonators in one step, the number of steps is reduced compared to if the FBAR and the Lamb wave device were made separately, thus reducing the manufacturing cost.

### Embodiment 3

FIG. 9 is a schematic cross-sectional view that shows a configuration of a transmitting/receiving filter according to Embodiment 3 of the present invention. Configurations that differ from those of Embodiment 1 will mainly be described below. Configurations similar to the above embodiment are assigned similar reference characters, and descriptions thereof are omitted or simplified.

A transmitting/receiving filter 301 of the present embodiment has a transmitting filter 301T, a receiving filter 301R, and a support substrate 301s. The transmitting filter 301T has an SMR as a first resonator ER31, and is formed in a first region R1 on the support substrate 301s. The receiving filter 301R has a Lamb wave device as a second resonator ER32, and is formed in a second region R2 on the support substrate 301s.

The first resonator ER31 has a lower electrode layer 331 (first electrode layer), an upper electrode layer 332 (second electrode layer), and a piezoelectric layer 333 (first piezoelectric layer). The lower electrode layer 331, the upper electrode layer 332, and the piezoelectric layer 333 are each formed in the first region R1 of the support substrate 301s, and the piezoelectric layer 333 is disposed between the lower electrode layer 331 and the upper electrode layer 332.

Materials for the lower electrode layer 331 and the upper electrode layer 332 are not limited; the lower electrode layer 331 and the upper electrode layer 332 are made of a metal material with a high acoustic impedance such as Ru (ruthenium) and Mo (molybdenum), for example. The thickness of the lower electrode layer 331 and the upper electrode layer 332 is not limited either, and is approximately 200 nm, for example.

The piezoelectric layer 333 is made of a piezoelectric single crystal substrate made of LT (lithium tantalate), LN (lithium niobate), or the like. The thickness of the piezoelectric layer 333 is not limited either, and is appropriately set according to the desired transmitting frequency band. In the present embodiment, the thickness is approximately 1000 nm.

The first resonator ER31 additionally has a first cavity C3 formed opposite to the lower electrode layer 331 in the first region R1 of the support substrate 301s. An acoustic multilayer film (acoustic reflective film) 336 is disposed in the first cavity C3. The acoustic multilayer film 336 is connected to the lower electrode layer 331 and has low pitch acoustic impedance layers 334 and high pitch acoustic impedance layers 335, each having a thickness of ¼ the wavelength λ of an elastic wave, alternately layered.

The second resonator ER32 has a piezoelectric layer 343 (second piezoelectric layer) and an interdigital transducer layer 344. The piezoelectric layer 343 is formed in the second region R2 of the support substrate 301s, and the interdigital transducer layer 344 is formed on the surface of the piezoelectric layer 343.

The piezoelectric layer 343 is made of an LT substrate or an LN substrate, for example, like the piezoelectric layer 333. The thickness of the piezoelectric layer 343 is the same as that of the piezoelectric layer 333 in the present embodiment (approximately 1000 nm). In the present embodiment, the piezoelectric layer 333 and the piezoelectric layer 343 are constituted of the same piezoelectric single crystal substrate 350.

The interdigital transducer layer 344, like the interdigital transducer layer 144 of Embodiment 1, includes a pair of interdigital transducers (IDT) and a pair of reflectors that sandwich the pair of interdigital transducers. The material for the interdigital transducer layer 344 is not limited, and is a metal or the like such as aluminum (Al), an Al-Cu alloy that includes minute amounts of Cu (copper) for increasing power durability, Cu, Ti (titanium), and Cr (chromium), for example. The electrode pitch of the IDTs, which are included in the interdigital transducer layer 344, is appropriately set according to the desired receiving frequency band. The thickness of the interdigital transducer layer 344 may be the same as the upper electrode layer 332 of the first resonator ER31, or be thinner.

The second resonator ER32 additionally has a second cavity C2. The second cavity C2 is formed in the second region R2 of the support substrate 301s opposite to the piezoelectric layer 343. As a result, ends that oscillate freely are formed on both surfaces of the piezoelectric layer 343.

The support substrate 301s is constituted of a silicon substrate, and supports both the transmitting filter 301T and the receiving filter 301R. The support substrate 301s, and the transmitting filter 301T and the receiving filter 301R are bonded to each other by a bonding layer 322.

The transmitting/receiving filter 301 of the present embodiment configured as stated above constitutes a duplexer by being installed on a circuit board 10s. According to the present embodiment, the transmitting filter 301T and the receiving filter 301R are constituted of the elastic wave resonators ER31 and ER32, which resonate at different oscillation modes from each other, and thus, like Embodiment 1, it is possible to provide a transmitting/receiving filter as one chip and a miniature duplexer that can prevent oscillation interference between the two filters.

### Embodiment 4

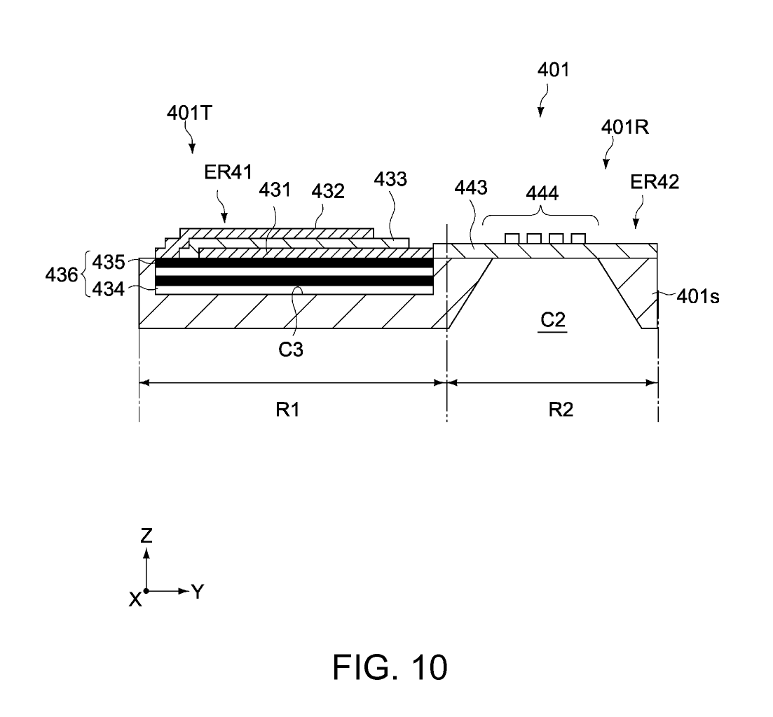

FIG. 10 is a schematic cross-sectional view that shows a configuration of a transmitting/receiving filter according to Embodiment 4 of the present invention. Configurations that differ from those of Embodiment 1 will mainly be described below. Configurations similar to the above embodiment are assigned similar reference characters, and descriptions thereof are omitted or simplified.

A transmitting/receiving filter 401 of the present embodiment has a transmitting filter 401T, a receiving filter 401R, and a support substrate 401s. The transmitting filter 401T has an SMR as a first resonator ER41, and is formed in a first region R1 on the support substrate 401s. The receiving filter 401R has a Lamb wave device as a second resonator ER42, and is formed in a second region R2 on the support substrate 401s.

The transmitting/receiving filter 401 of the present embodiment differs from the above-mentioned Embodiment 3 in that a piezoelectric layer 433 (first piezoelectric layer) of the first resonator ER41 and a piezoelectric layer 443 (second piezoelectric layer) of the second resonator ER42 are constituted of a piezoelectric thin film made of AN or the like formed by sputtering. The thickness of the piezoelectric thin film is set according to the center frequency of the first resonator ER41, and is approximately 500 nm, for example.

The first resonator ER41 has a lower electrode layer 431 and an upper electrode layer 432, which are opposite to each other through the piezoelectric layer 433, and an acoustic multilayer film (acoustic reflective film) 436, which is connected to the lower electrode layer 431. The lower electrode layer 431 and the upper electrode layer 432 are made of a metal material such as Ru and Mo, for example, and the acoustic multilayer film 436 has low pitch acoustic impedance layers 434 and high pitch acoustic impedance layers 435 layered together.

The second resonator ER42 is constituted of a Lamb wave device in which an interdigital transducer layer 444 is formed on the piezoelectric layer 443, and the center frequency of the second resonator ER42 is set by the IDT pitch of the interdigital transducer layer 444. An insulating film made of a silicon oxide or the like is formed between the support substrate 401s and the piezoelectric layer 443, but this is omitted from the drawings.

The transmitting/receiving filter 401 of the present embodiment configured as stated above constitutes a duplexer by being installed on a circuit board 10s. According to the present embodiment, the transmitting filter 401T and the receiving filter 401R are constituted of the elastic wave resonators ER41 and ER42, which resonate at different oscillation modes, and thus, as in Embodiment 1, it is possible to provide a transmitting/receiving filter on one chip and a miniature duplexer that can prevent oscillation interference between the two filters.

### Embodiment 5

In conventional devices, the cavity structure was used for Lamb wave devices, but in recent years, an SMR-type Lamb wave device has also been developed, and is highly effective. An SMR-type Lamb wave device can also be applied to a one-chip duplexer of the present invention. In particular, in a case where the BAW part is of an SMR type, if the Lamb wave device is also the SMR type, the acoustic multilayer films thereof can be formed in one step, thus simplifying the process.

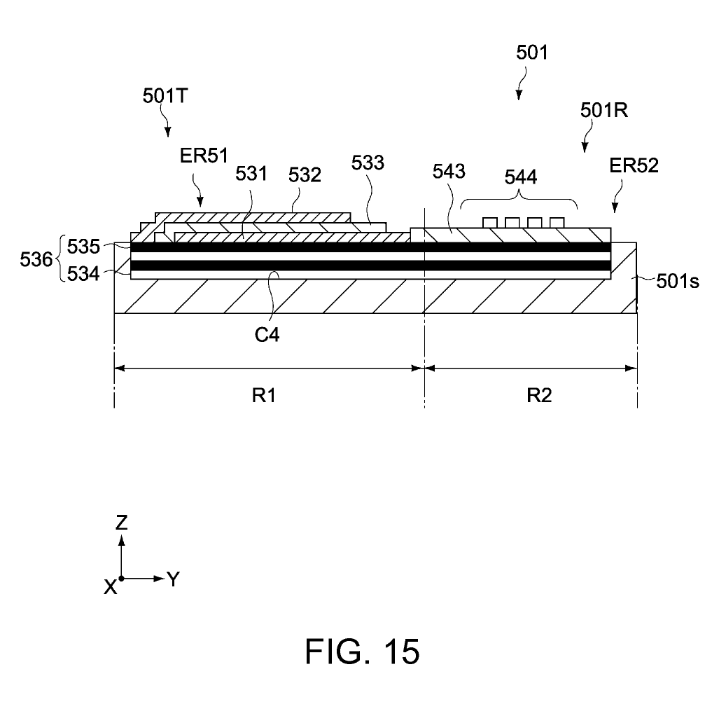

FIG. 15 is a schematic cross-sectional view that shows a configuration of a transmitting/receiving filter according to Embodiment 5 of the present invention. Configurations that differ from those of Embodiment 1 will mainly be described below. Configurations similar to the above embodiment are assigned similar reference characters, and descriptions thereof are omitted or simplified.

A transmitting/receiving filter 501 of the present embodiment has a transmitting filter 501T, a receiving filter 501R, and a support substrate 501s. The transmitting filter 501T has an SMR as a first resonator ER51, and is formed in a first region R1 on the support substrate 501s. The receiving filter 501R has a Lamb wave device as a second resonator ER52, and is formed in a second region R2 on the support substrate 501s.

The transmitting/receiving filter 501 of the present embodiment differs from the above-mentioned Embodiment 3 in that a piezoelectric layer 533 (first piezoelectric layer) of the first resonator ER51 and a piezoelectric layer 543 (second piezoelectric layer) of the second resonator ER52 are constituted of a piezoelectric thin film made of AN or the like formed by sputtering. The thickness of the piezoelectric thin film is set according to the center frequency of the first resonator ER51, and is approximately 500 nm, for example.

The transmitting/receiving filter 501 additionally has a cavity C4 formed in the first region R1 and the second region R2 of the support substrate 501s. An acoustic multilayer film (acoustic reflective film) 536 is disposed in the cavity C4. The acoustic multilayer film 536 has low pitch acoustic impedance layers 534 and high pitch acoustic impedance layers 535, each having a thickness of ¼ the wavelength λ of an elastic wave, alternately layered.

The first resonator ER51 has a lower electrode layer 531 and an upper electrode layer 532 opposite to each other through the piezoelectric layer 533. The lower electrode layer 531 is disposed on the acoustic multilayer film (acoustic reflective layer) 536. The lower electrode layer 531 and the upper electrode layer 532 are made of a metal material such as Ru and Mo, for example.

The second resonator ER52 is constituted of a Lamb wave device in which an interdigital transducer layer 544 is formed on the piezoelectric layer 543, and the center frequency of the second resonator ER52 is set by the IDT pitch of the interdigital transducer layer 544. The piezoelectric layer 543 is disposed on the acoustic multilayer film 536. In the SMR-type Lamb wave device, by using the acoustic multilayer film 536 having 10 or more layers, for example, of the low pitch acoustic impedance layers 534 and the high pitch acoustic impedance layers, elastic waves can be sufficiently confined.

The transmitting/receiving filter 501 of the present embodiment configured as stated above constitutes a duplexer by being installed on a circuit board 10s. According to the present embodiment, the transmitting filter 501T and the receiving filter 501R are constituted of the elastic wave resonators ER51 and ER52, which resonate at different oscillation modes, and thus, as in Embodiment 1, it is possible to provide a transmitting/receiving filter on one chip and a miniature duplexer that can prevent oscillation interference between the two filters.

The embodiments of the present invention have been described above, but the present invention is not limited to the above embodiments, and it is apparent that various modifications can be made within the scope of the present invention.

For example, in the above embodiments, the resonator of the transmitting filter is constituted of a BAW resonator (FBAR or SMR) and the resonator of the receiving filter is mainly made of a Lamb wave filter, but the present invention is not limited to this; the resonator of the transmitting side may be constituted of the Lamb wave device and the resonator of the receiving side may be constituted of the BAW device.

Also, in the embodiments above, the transmitting filter and the receiving filter are both formed on one surface of the support substrate, but the present invention is not limited to this; for example, the transmitting filter may be formed on one side of the support substrate while the receiving filter is formed on the other side of the support substrate.

It will be apparent to those skilled in the art that various modification and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A filter device, comprising:
a first filter that includes a first elastic wave resonator configured to resonate in a first oscillation mode;
a second filter that includes a second elastic wave resonator configured to resonate in a second oscillation mode that differs from the first oscillation mode; and
a support substrate that supports both the first filter and the second filter.

2. The filter device according to claim 1,
wherein the first elastic wave resonator is a bulk wave resonator, and
wherein the second elastic wave resonator is a Lamb wave resonator or a surface acoustic wave resonator.

3. The filter device according to claim 2,
wherein the bulk wave resonator is a film bulk acoustic resonator (FBAR).

4. The filter device according to claim 2,
wherein the bulk wave resonator is a solid mounted resonator (SMR).

5. A filter device, comprising:
a support substrate having a first region, and a second region formed on a same plane as the first region;
a first filter that is formed in the first region, the first filter including a first elastic wave resonator configured to resonate in a first oscillation mode; and
a second filter that is formed in the second region, the second filter including a second elastic wave resonator configured to resonate in a second oscillation mode that differs from the first oscillation mode.

6. The filter device according to claim 5,
wherein the first elastic wave resonator has a first electrode layer formed in the first region, a first piezoelectric layer formed on the first electrode layer, and a second electrode layer formed on the first piezoelectric layer, and
wherein the second elastic wave resonator has a second piezoelectric layer formed in the second region, and an interdigital transducer layer formed on the second piezoelectric layer.

7. The filter device according to claim 6,
wherein the first elastic wave resonator further has a first cavity formed in the first region opposite to the first electrode layer.

8. The filter device according to claim 6,
wherein the first elastic wave resonator further has an acoustic multilayer film formed in the first region opposite to the first electrode layer.

9. The filter device according to claim 6,
wherein the second elastic wave resonator further has a second cavity formed in the second region opposite to the second piezoelectric layer.

10. The filter device according to claim 6,
wherein the first piezoelectric layer and the second piezoelectric layer are formed at the same thickness.

11. The filter device according to claim 5,
wherein the support substrate is a silicon substrate.

12. A method for manufacturing a filter device, comprising:
forming a first electrode layer that is patterned into a prescribed shape on a first surface of the support substrate;
forming a piezoelectric layer on the first electrode layer and the first surface;
forming a second electrode layer on a first piezoelectric layer part of said piezoelectric layer opposite to the first electrode layer, the first piezoelectric layer part being formed on the first electrode layer;
forming an interdigital transducer layer as a third electrode layer on a second piezoelectric layer part of said piezoelectric layer, the second piezoelectric layer part being formed on the first surface; and
forming a first cavity opposite to the first electrode layer and a second cavity opposite to the second piezoelectric layer on a second surface of the support substrate opposite to the first surface of the support substrate.

13. A method for manufacturing a filter device, comprising:
forming a first electrode layer that is patterned into a prescribed shape on a first surface of a piezoelectric substrate;
bonding a support substrate to the first surface such that the first electrode layer is interposed therebetween;
forming a second electrode layer opposite to the first electrode layer through the piezoelectric substrate, and an interdigital transducer layer as a third electrode layer opposite to the support substrate through the piezoelectric substrate on a second surface of the piezoelectric substrate opposite to the first surface of the piezoelectric substrate; and
forming, in the support substrate, a first cavity opposite to the first electrode layer and a second cavity opposite to the third electrode layer through the piezoelectric substrate.

14. A duplexer, comprising:
a first filter for transmitting that includes a first elastic wave resonator configured to resonate in a first oscillation mode;
a second filter for receiving that includes a second elastic wave resonator configured to resonate in a second oscillation mode that differs from the first oscillation mode; and
a support substrate that supports both the first filter and the second filter.

15. The duplexer according to claim 14, further comprising:
a circuit board on which the support substrate is mounted;
an antenna terminal provided on the circuit board, the antenna terminal being connected to both the first filter and the second filter; and
a phase shifter provided between the antenna terminal and the second filter.
